(19) United States
(12) Patent Application Publication
(10) Pub. No.: US 2014/0230901 A1
(43) Pub. Date: Aug. 21, 2014

(54) Organic Solar Cell Comprising an Intermediate Layer with Asymmetrical Transport Properties

(71) Applicant: Merck Patent GmbH, Darmstadt (DE)

(72) Inventors: Christoph Brabec, Linz (AT); Christoph Waldauf, Linz (AT)

(73) Assignee: Merck Patent GmbH, Darmstadt (DE)

(21) Appl. No.: 14/262,869

(22) Filed: Apr. 28, 2014

Related U.S. Application Data
(63) Continuation of application No. 10/559,009, filed on May 15, 2006.

(51) Int. Cl. H01L 51/44

(52) U.S. Cl. CPC H01L 51/44
USPC 136/263

(57) ABSTRACT

The invention relates to an organic solar cell comprising a photoactive layer consisting of two molecular components, namely an electron donator and an electrode acceptor, and comprising two electrodes provided on both sides of the photoactive layer, whereby an intermediate layer having an asymmetric conductivity is placed between at least one of the electrodes and the photoactive layer.

### CROSS-REFERENCE TO RELATED APPLICATIONS

This application is a divisional patent application of co-pending U.S. Utility Application Ser. No. 10/559,009, in which 35 U.S.C.§371 requirements were completed on May 15, 2006, and which is a U.S. national stage entry of PCT/EPO4/50915, filed May 26, 2004, which claims priority to German patent application DE 103 26 546.5, filed Jun. 12, 2003. The contents of all parent applications are hereby incorporated by reference.

The present invention concerns an organic solar cell comprising a photoactive layer composed of two molecular components, namely an electron donor and an electron acceptor, and comprising two electrodes provided on either side of the photoactive layer.

In organic solar cells and photodetectors (especially bulk heterojunction polymer solar cells), a decrease in parallel resistance is observed with increasing light intensity. This phenomenon is known as photoshunt. Photoshunt causes a decrease in fill factor, thereby reducing the efficiency of the solar cell.

A way to increase the series resistance and selectivity of the contacts is known from WO 01/84645 A1.

To date, however, there are no known solutions suitable for increasing the parallel resistance.

It is, therefore, an object of the present invention to increase the parallel resistance of an organic solar cell in order to reduce the losses that occur as a result of low parallel resistance.

According to one aspect, the present invention provides a photovoltaic cell comprising a photoactive layer and two electrodes and characterized by at least one intermediate layer with asymmetrical conductivity, disposed between at least one of the electrodes and the photoactive layer.

The term “asymmetrical conductivity” denotes asymmetrical mobility for the various charge carriers. One advantage of the present invention is that as long as the material of the intermediate layer is suitably selected, particularly in the case of organic solar cells, no doping of the intermediate layer is necessary. This also eliminates all disadvantages such as stabilization problems with the dopants, especially in organic layers.

The intermediate layer preferably has a (large) bandgap that is at least equal to or greater than the bandgap of the photoactive layer. It is, for example, in the range of 1.7 to 6.1 eV (electron volts), or preferably in a range of 2.5 to 3.7 eV.

A layer with a large bandgap is preferably at least semitransparent or completely transparent.

Using a layer of this kind prevents one type of charge carrier (electrons or defect electrons [or vacancies or holes]) from passing from one electrode to the other electrode. The parallel resistance (at least for one type of charge carrier) can be increased considerably in this way.

In a preferred embodiment of the invention, the photovoltaic cell comprises, between each of the two electrodes and the photoactive layer, an intermediate layer with a large bandgap and asymmetrical conductivity.

A layer with a large bandgap is substantially transparent or at least semitransparent. The term “asymmetrical conductivity” denotes asymmetrical mobility for the various charge carriers. If two such layers are used, one layer can conduct electrons and the other layer defect electrons. Connecting the two layers in series greatly increases the parallel resistance for both charge carriers. This prevents one of the two types of charge carriers from passing from one electrode to the other electrode. This also reduces losses due to the recombination of minority charge carriers in the electrodes of the solar cell.

In a further embodiment of the present invention, the photoactive layer comprises one region with electron donors and one region with electron acceptors. The electron acceptor region is assigned to the cathode. The photovoltaic cell is characterized in that the intermediate layer is disposed between the electron acceptor region and the cathode (negative electrode) and comprises a material that conducts current primarily via electrons.

In another embodiment of the present invention, the photoactive layer comprises one region with electron donors and one region with electron acceptors. The electron donor region is assigned to the anode (positive electrode). The photovoltaic cell is characterized in that the intermediate layer is disposed between the electron donor region and the anode and comprises a material that conducts current primarily via defect electrons (holes, positive charges).

Thus, the asymmetry of the conductivity is assigned to one of the electrodes or one of the active layers. That is, between the cathode and the electron acceptor region is a layer composed of an electron conductor. That is, in addition, between the anode and the electron donor region is a layer composed of a defect electron conductor.

In another preferred embodiment of the invention, the electron-conducting intermediate layer between the electron acceptors and the cathode comprises TiO₂ or C₆₀.

In a preferred embodiment of the invention, the photovoltaic cell is characterized in that the defect-electron-conducting intermediate layer comprises PEDOT. PEDOT (poly-3,4-ethylenedioxythiophene) is a conductive polymer based on a heterocyclic thiophene that polymerizes by means of diether bridges.

A further advantageous embodiment of the present invention is characterized in that the conduction band of the electron-conducting intermediate layer is matched to the highest occupied molecular orbital of the electron acceptor. This prevents the formation of potential differences between the intermediate layer and the electron acceptor region, which can have a negative impact on the output and efficiency of the solar cell.

Another advantageous embodiment of the present invention is characterized in that the conduction band of the defect electron (hole) conducting intermediate layer is matched to the lowest unoccupied molecular orbital of the electron donor. This prevents the formation of potential differences between the intermediate layer and the electron donor region, which can have a negative impact on the output and efficiency of the solar cell.

The inventive photovoltaic cell is preferably an organic photovoltaic cell.

The invention is described hereinafter with reference to the appended drawing, in which:

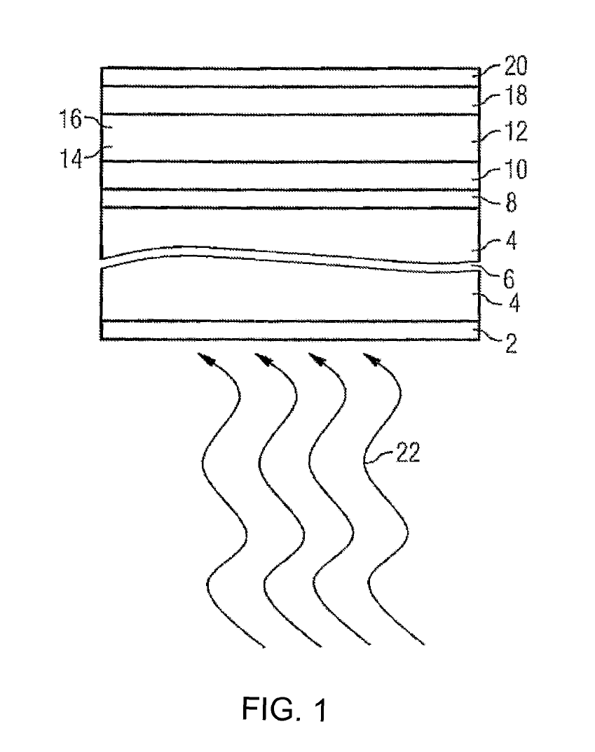

FIG. 1 depicts a sectional view through a solar cell according to an embodiment of the present invention.

FIG. 1 shows a cross section through a solar cell according to the present invention. The solar cell is applied to a carrier material or substrate 4. Substrate 4 can be made of glass, plastic, a crystal or a similar material. Substrate 4 is depicted with a disconnect 6 to show that the thickness of the substrate 4 is immaterial to the present invention and can vary. The substrate merely serves to provide the solar cell with suitable mechanical strength and optionally with surface protection. The substrate is provided, on its side facing the incident light, with an antireflection coating 2 (or treatment) to reduce or prevent losses due to reflection.

The first layer 8 on the substrate constitutes an electrode 8 of the solar cell. It is substantially unimportant whether the electrode is a cathode or an anode.

Let us assume, without limitation, that light enters the depicted solar cell through substrate 4 from below. First electrode 8 should therefore be made, for example, of Al, Cu, . . . , ITO (indium/tin oxide) or the like. It is to be noted that the electrode facing the incident light (electrode 8 in this case) is preferably transparent or semitransparent and/or has a lattice structure.

For the sake of simplicity, let us assume that electrode 8 disposed on substrate 4 is a cathode. Applied to the cathode is a first intermediate layer 10 with a large bandgap and asymmetrical conductivity, i.e., a conductivity provided by the mobility of (excess) electrons. Due to the large bandgap, the material is substantially transparent or at least semitransparent. Only electrons are able to pass through this intermediate layer. The material and the dimensions of first intermediate layer 10 can be selected to suit the properties of the active layer or electron acceptor. In the case of organic solar cells, this can be achieved by matching the bandgap to the highest occupied molecular orbital of the electron acceptor.

The further properties of the intermediate layer 10, such as thickness and refractive index, can be selected so that intermediate layer 10 acts as an antireflection layer between electrode 8 and the next layer thereafter.

It is to be noted that the intermediate layer 10 facing the incident light, i.e. preferably electrode 8, can have a lattice structure.

Intermediate layer 10 is overlain by the active layer per se. The composition of the active layer 12 is substantially unimportant to the present invention. Active layers normally contain one region with electron donors 16 and one region with electron acceptors 14, the two regions for example being intermingled via a depletion layer and/or being connected to each other. The charge carriers (electron-hole pairs) generated in the active layer by incident light are each drained separately into the adjacent layers.

The active layer can also be composed, for example, of a conventional amorphous semiconductor with a pn junction. However, the present invention lends itself very particularly advantageously to use in organic solar cells for example comprising P3HT/PBCM, CuPc/PTCBI, ZNPC/C₆₀ or a conjugated polymer component and a fullerene component.

In the solar cell depicted, the side 14 of active layer 12 facing toward the substrate is assigned to the electron acceptor and the side 16 facing away from the substrate to the electron donor.

Disposed over active layer 12 on the side of the electron donors 16 is a second intermediate layer 18 with a large bandgap and asymmetrical conductivity. The conductivity of second intermediate layer 18 is based on the mobility of defect electrons. Due to its large bandgap, the material is also substantially transparent or at least semitransparent. Only defect electrons are able to pass through this intermediate layer. The material and the dimensions of this second intermediate layer 18 can be selected so that they suit the properties of the active layer, i.e., the properties of the electron donor. In the case of organic solar cells, this can be achieved by matching the bandgap of the intermediate layer to the lowest unoccupied molecular orbital of the electron donor. To summarize, neither an electron nor a defect electron can pass directly from one electrode to the other electrode through the two series-connected, asymmetrically conducting intermediate layers 10 and 18, since either the first intermediate layer or the second intermediate layer constitutes an impenetrable barrier. Thus, no charge carrier can pass directly from the one to the other electrode. The parallel resistance therefore increases in comparison to a conventionally constructed solar cell, and the efficiency of the solar cell therefore also increases.

The further properties of intermediate layer 18, such as thickness and refractive index, can be selected so that intermediate layer 18 forms an antireflection layer between active layer 12 and the next layer thereafter. This can be advantageous particularly in tandem photovoltaic cells or multicells.

The further properties of intermediate layer 18, such as thickness and refractive index, can be selected so that intermediate layer 18 (together with an electrode following thereafter) forms a reflection layer between active layer 12 and the next layer thereafter. This can be advantageous particularly in the case of single photovoltaic cells, since light that has passed through the active layer can, after being reflected, again generate charge-carrier pairs in the depletion layer.

The intermediate layer facing away from the incident light (layer 10 or 18, depending on the embodiment) need not necessarily be transparent or semitransparent. This means that the bandgap of the intermediate layer facing away from the incident light does not absolutely have to be large.

On the other hand, the intermediate layer facing the incident light (layer 10 or 18, depending on the embodiment) must be transparent or at least semitransparent so that the incident light can reach the active layer. This means that the bandgap of the intermediate layer facing the incident light must be at least exactly as large as the bandgap of the material of the active layer facing the incident light.

Second intermediate layer 18 is followed by electrode layer 20, which is an anode in the example given. The electrode material of the anode can in the present embodiment be composed for example of Ag, Au, Al, Cu, . . . ITO or the like. Since the anode faces away from the incident light in the present example, it is not subject to restrictions of any kind with respect to thickness, transparency or any other restrictions. The anode can further be coated with a protective layer (not shown).

The wavy arrows 22 indicate the direction of the incident light.^{1 1}TRANSLATOR'S NOTE: Sic, even though the arrows in the drawing are not wavy and “22” denotes a different (and unidentified) element. Sentence lifted unmodified from related PCT application WO 2004/1126161 A2.

It goes without saying that the solar cell can also, conversely, be constructed on a for example non-transparent substrate 4, in which case the light can then be incident from above. However, an “inverse” structure of this kind entails the disadvantage that the structures and layers facing the incident light are exposed to environmental influences such as atmospheric oxygen, dust and the like, which can rapidly damage the solar cell or make it unusable.

If an “inverse” structure is used, for example the antireflection coating 2 would have to be provided on the other side of the solar cell.

The invention can also be used with conventional monocrystalline or polycrystalline solar cells. Here again, the intermediate layers 10, 18 would be disposed between the electrodes and the active layer.

The invention makes it possible to increase the parallel resistance of solar cells and photodetectors. This reduces the “photoshunt” effect and thereby increases the fill factor and thus the efficiency of the solar cell. The ideality of the diode also increases as a result.

The present invention is based on the use of intermediate layers having a large bandgap and asymmetrical mobility for the various charge carriers. A further advantage of the invention is that doping of the intermediate layers is unnecessary, and the problems posed by the stabilization of dopants in organic materials can thus be avoided.

The intermediate layers can be deposited both from the gas phase and from solution, thereby reducing the cost of processing and producing the intermediate layers.

In connection with the use of (semi)transparent layers with a large band bandgap and sharply asymmetrical conductivity between the electrode and the photoactive semiconductor layer, it is to be noted that the layer with high electron mobility is to be applied between the active layer and the negative electrode, and the layer with high hole (defect electron) mobility is to be applied between the active layer and the positive electrode. It is also to be noted that the conduction band of the layer with high electron mobility is to be matched to the highest occupied molecular orbital of the electron acceptor, and the valence band of the layer with high hole mobility to the lowest unoccupied molecular orbital of the electron donor.

Given sufficient mobility of the charge carriers in the intermediate layers, additional doping is not necessary.

It is, moreover, readily apparent that the bandgaps of the at least two intermediate layers can differ. In addition, it will be appreciated that designs comprising a plurality of intermediate layers are also intended to fall within the protective scope of the present claims, since multilayer intermediate layers of this kind can also be considered a single “composite intermediate layer.” It is, moreover, clear that the present invention can naturally also be used with tandem or multi solar cells. In contemplating both the individual layers of the solar cell and the tandem solar cell as a whole, all possible combinations comprising at least one intermediate layer between a photoactive layer and an electrode, as well as constructions in which there is an intermediate layer between each photoactive layer and electrode, also fall within the protective scope of the present claims.

The asymmetrical transport properties of the intermediate layers serve to prevent the formation of continuous conduction paths for only one type of charge carrier. This increases parallel resistance. It simultaneously decreases the likelihood that minority charge carriers will reach the respective other electrode, thereby reducing losses due to the recombination of charge carriers of opposite charge in the metal electrodes.

1. An organic photovoltaic cell comprising:
two electrodes and
an organic photoactive layer comprising a conjugated polymer and a fullerene, the organic photoactive layer being disposed between the two electrodes,
wherein the organic photovoltaic cell is configured to be oriented to an incident light source, wherein the electrode disposed between the organic photoactive layer and the incident light is transparent or semitransparent, and
the organic photovoltaic cell further comprises two intermediate layers each intermediate layer having asymmetrical conductivity and each intermediate layer being disposed between each of the two electrodes and the organic photoactive layer.

2. The organic photovoltaic cell of claim 1, wherein one of the intermediate layers conducts electrons and the other conducts defect electrons (holes).

3. The organic photovoltaic cell of claim 2, wherein one of the electrodes is a cathode, and the intermediate layer disposed between the said cathode and the organic photoactive layer has asymmetrical conductivity that is provided by the mobility of electrons.

4. The organic photovoltaic cell of claim 2, wherein one of the electrodes is an anode, and the intermediate layer disposed between the said anode and the organic photoactive layer has asymmetrical conductivity that is provided by the mobility of defect electrons.

5. The organic photovoltaic cell as in claim 1, wherein the intermediate layer has a bandgap that is larger than or equal to the bandgap of the organic photoactive layer.

6. The organic photovoltaic cell of claim 1, wherein the organic photoactive layer comprises one region with electron donors and one region with electron acceptors, a cathode being assigned to the electron acceptor region, wherein the intermediate layer that is disposed between the electron acceptor region and the cathode comprises a material that conducts current primarily via electrons.

7. The organic photovoltaic cell of claim 6, wherein the conduction band of the electron-conducting intermediate layer is matched to the highest occupied molecular orbital of the electron acceptor.

8. The organic photovoltaic cell of claim 1, wherein the organic photoactive layer comprises one region with electron donors and one region with electron acceptors, an anode being assigned to the electron donor region, characterized in that the intermediate layer is disposed between the electron donor region and the anode and comprises a material that conducts current primarily via defect electrons.

9. The organic photovoltaic cell of claim 8, wherein the valence band of the defect-electron-conducting intermediate layer is matched to the lowest unoccupied molecular orbital of the electron donor.

10. The organic photovoltaic cell of claim 2, wherein the electron-conducting intermediate layer comprises TiO₂ or C₆₀.

11. The organic photovoltaic cell of claim 2, wherein the defect-electron-conducting intermediate layer comprises PEDOT.

12. The organic photovoltaic cell of claim 2, wherein the organic photoactive layer comprises P3HT and PCBM.
